(19) United States
(12) Patent Application Publication
(10) Pub. No.: US 2002/0179247 A1
(43) Pub. Date: Dec. 5, 2002

(54) Nozzle for introduction of reactive species in remote plasma cleaning applications

(76) Inventors: Matthew F. Davis, Brookdale, CA (US); Huutri Dao, San Jose, CA (US); Ashok K. Das, Cupertino, CA (US)

Correspondence Address: APPLIED MATERIALS, INC., 2881 SCOTT BLVD. M/S 2061, SANTA CLARA, CA, 95050, US

(21) Appl. No.: 09/874,560

(22) Filed: Jun. 4, 2001

(51) Int. Cl. C23F 1/00; C23C 16/00

(52) U.S. Cl. 156/345.33; 118/715; 118/723 IR; 156/345.48

(57) ABSTRACT

A nozzle for a plasma reactor of the type having a processing chamber, with the nozzle comprising a body having interior and exterior sides and a first end. The interior side defines a throughway having a longitudinal axis, and the first end includes an opening in fluid communication with the throughway. The body extends from the first end, terminating in a second end, and includes an aperture formed proximate to the second end. The aperture is configured to create, from a flow of fluid propagating through the throughway and exiting said aperture, a sheet of the fluid moving tangentially to a flow cell established in the processing chamber.

### BACKGROUND OF THE INVENTION

The present invention relates to semiconductor processing. More particularly, the present invention relates to cleaning of semiconductor processing chambers.

During fabrication of integrated circuits on substrates, semiconductor, dielectric, and conductor materials deposit on the surfaces of the processing chamber in which the substrates are disposed. This deposited material, referred to as residue, must be removed periodically to prevent contamination of the substrates being processed in the processing chamber. Otherwise, control of the process conditions becomes difficult, which can result in inconsistent processing results and failure.

One conventional method of removing the process residue is a “wet-cleaning” process in which the processing chamber is opened to the atmosphere and an operator scrubs-off accumulated process residue with an acid or solvent. To provide consistent processing chamber characteristics, after the wet-cleaning process, the processing chamber is “seasoned” by pumping down the processing chamber for an extended period of time, typically 2 to 3 hours. Thereafter, a series of dummy wafers are processed until the processing chamber provides consistent and reproducible results.

In the competitive semiconductor industry, the increased cost per substrate that results from the extended processing chamber downtime during the wet-cleaning and seasoning process steps is highly undesirable. Also, the wet-cleaning and seasoning process often provide inconsistent and variable results. In particular, an operator performs the wet-clean process, resulting in variations in processing chamber surface properties and low process reproducibility. Thus, it is desirable to have a cleaning process that can quickly and reliably remove the process residue formed on the surfaces in the processing chamber.

One method that overcomes some of the drawbacks associated with wet-cleaning employs a plasma of radicals formed from fluorine-containing molecules, such as NF₃. This cleaning process is referred to as an in-situ cleaning process. The in-situ cleaning process is typically performed after a certain number of substrates are processed in the processing chamber.

One example of an in-situ plasma cleaning process forms the plasma in the processing chamber that is to be cleaned. In such a chamber, either capacitively coupling or inductively coupling RF energy into the processing chamber may form the plasma. FIG. 1 shows a plasma reactor 10, known as a decoupled plasma source chamber, employs an inductively-coupled plasma to clean a processing chamber 12 of plasma reactor 10. Processing chamber 12 has a grounded, conductive, cylindrical sidewall 14 and a dielectric ceiling 16 that may have any shape desired, e.g., arcuate or rectangular. As shown, ceiling has an arcuate shape, e.g., dome-like. Reactor 10 includes a wafer pedestal 18 disposed within processing chamber 12. Wafer pedestal 18 includes a surface 20 upon which a semiconductor substrate (not shown) is supported. A cylindrical inductor coil 22 surrounds dielectric ceiling 16 and, therefore, an upper portion of processing chamber 12. A grounded body 24 shields inductor coil 22. An RF generator 26 is in electrical communication with inductor coil 22 through a conventional active RF match network 28. The winding of coil inductor 22 furthest away from pedestal 18 is connected to the “hot” lead of RF generator 26, and the winding closest to pedestal 18 is connected to ground. An additional RF power supply or generator 30 is in electrical communication with an interior conductive portion 32 of pedestal 18. An exterior portion 36 of pedestal 18 forms a grounded conductor that is electrically insulated from the interior conductive portion 32.

One or more gas sources, shown as 38, are in fluid communication with processing chamber 12 via feed line 40. Fluids traversing feed line 40 flow into processing chamber 12 through a nozzle 44. Nozzle 44 may be one of a plurality of nozzles spaced about processing chamber 12. A pump system 46 controls the chamber pressure. To that end, sidewall 14 includes an exhaust port 48 and an exhaust conduit 49 that places pump system 46 in fluid communication with processing chamber 12. Pump system 46 includes a turbo-molecular pump 50, a roughing pump 51 and a throttle gate valve 52. Turbo-molecular pump 50 is selectively placed in fluid communication with roughing pump 51 through an exhaust line 53 having a foreline valve 53a disposed therein. Roughing pump 51 is also selectively placed in fluid communication with exhaust conduit 49 via pump-out line 55 having a rough pump-out valve 55a disposed therein. Throttle gate valve 52 is connected between turbo-molecular pump 50 and exhaust port 48. Throttle gate valve 52 varies the area of flow path 56 into turbo-molecular pump 50. In this manner, throttle gate valve 52 typically regulates the chamber pressure in cooperation with turbo-molecular pump 50. Turbo-molecular pump 50 maintains a constant vacuum and throttle gate valve 52 is adjusted to provide flow path 56 with a cross-sectional area to achieve a desired chamber pressure.

During an in-situ cleaning process, turbo-molecular pump 50 is activated to produce a vacuum in the range of 1 to 200 milliTorr and a plasma 60 is struck in processing chamber 12. Throttle gate valve 52 is completely retracted into throttle gate valve housing 54, formed into one end of exhaust conduit 49, to maximize the cross-sectional area of flow path 56. The plasma includes fluorine radicals that move under a pressure differential, created by turbo-molecular pump 50, from processing chamber 12 and into exhaust port 48. The fluorine radicals entering exhaust port 48 flow through flow path 56, into turbo-molecular pump 50. These fluorine radicals react with the residue deposited on chamber components, forming volatile compounds. The volatile compounds are exhausted from processing chamber 12 through pump exhaust 62 that is located in roughing pump 51. The large area presented by exposed surfaces of processing chamber 12 requires many hours to clean. This significantly reduces the number of substrates that can be processed in a given time period and increases capitalization costs. The cleaning time may be reduced, but at the expense of damaging surfaces in processing chamber 12, due to the relatively high power employed to strike the plasma. In addition, cleaning of pump system 46 is not very efficient, because the flux of reactive radicals entering pump system 46 is greatly reduced, compared to the flux of reactive radicals in processing chamber 12. This may result from either recombination of the reactive radicals that form less reactive non-dissociated species or from the reactive radicals already reacting with residue from other parts of the plasma reactor. As a result, pump system 46 may contain residue after an in-situ cleaning process has occurred.

Another cleaning process that employs a plasma generates the plasma in a chamber that differs from the chamber to be cleaned. This is referred to as a remote plasma cleaning. The chamber in which the plasma is formed is referred to as a remote plasma source. The remote plasma source is in fluid communication with the processing chamber to be cleaned. The high breakdown efficiency of the plasma formed by the remote plasma source results in a higher etch rate than is obtained with an in-situ plasma. In addition, the plasma formed by the remote plasma source efficiently and adequately cleans the residue from the surfaces of the processing chamber while causing less damage thereto.

Remote plasma sources often employ a fluorine compound, such as CF₄, C₂F₆ and the like. The shape, size, and distance of the remote plasma source from the chamber to be cleaned, as well as the gases employed affect the chemical reactivity and nature of the plasma species. For example, the greater the distance between the remote plasma source and the processing chamber, the greater the quantity of recombination of the radicals into a less reactive non-dissociated species. The cleaning rate is much slower with the non-dissociated species than with the dissociated radicals. In addition, achieving range and directional control of radical trajectories to remote surfaces of the processing chamber has proved challenging. As a result, many of the more remote regions of the processing chamber may not be exposed to a sufficient flux of radicals. Thus, a large amount of the residue may remain in the processing chamber, which may cause processing difficulties or contaminate a substrate disposed therein.

What is needed, therefore, is an in-situ cleaning technique that provides the benefits associated with a plasma formed within a remote plasma source, while increasing the probability that dissociated radicals will impinge upon those surfaces of a processing chamber in need of being cleaned.

### SUMMARY OF THE INVENTION

Provided is a nozzle for a plasma reactor of the type having a processing chamber, with the nozzle comprising a body having interior and exterior sides and a first end, with the interior side defining a throughway having a longitudinal axis, and the first end including an opening in fluid communication with the throughway. The body extends from the first end, terminating in a second end. An aperture is disposed proximate to the second end. The aperture is configured to create, from a flow of fluid propagating through the throughway and exiting said aperture, a sheet of the fluid moving tangentially to a flow cell established in the processing chamber.

### BRIEF DESCRIPTION OF THE DRAWINGS

FIG. 1 is a cross-sectional view of a prior art semiconductor processing system;

FIG. 2 is a cross-sectional view of a semiconductor processing system employing a remote plasma source;

FIG. 3 is a front perspective view of a nozzle employed in the semiconductor processing system shown above in FIG. 2;

FIG. 4 is an exploded perspective view of the nozzle shown above in FIG. 3;

FIG. 5 is a front view of first alternate embodiment of a nozzle employed in the semiconductor processing system shown above in FIG. 2;

FIG. 6 is a cross-sectional view of the nozzle shown above in FIG. 5, taken along lines 6-6;

FIG. 7 is a cross-sectional view of a processing chamber showing the flow pattern of reactive radicals exiting the nozzle described above with respect to FIGS. 5 and 6;

FIG. 8 is a front view of a second alternate embodiment of a nozzle employed in the semiconductor processing system shown above in FIG. 2;

FIG. 9 is a cross-sectional view of the nozzle shown above in FIG. 8, taken along lines 9-9;

FIG. 10 is a perspective view of the nozzle shown above in FIGS. 8 and 9 demonstrating the flow of radicals exiting therefrom;

FIG. 11 is a cross-sectional view of the processing chamber, shown above in FIG. 7, demonstrating the flow pattern of reactive radicals exiting the nozzle described above with respect to FIGS. 8 and 9;

FIG. 12 is a cross-sectional view of the semiconductor processing system in accordance with an alternate embodiment of the present invention;

FIG. 13 is a is a flow diagram showing a cleaning procedure employed in the semiconductor processing system shown above in FIG. 12;

FIG. 14 is a computer model of a flow of reactive radicals in the processing chamber shown above in FIG. 12;

FIG. 15 is a perspective view of the nozzle shown above in FIGS. 8 and 9, in accordance with an alternate embodiment;

FIG. 16 is a perspective view of the nozzle shown above in FIGS. 8 and 9, in accordance with a second alternate embodiment;

FIG. 17 is a cross-sectional view of a semiconductor processing system in accordance with the present invention;

FIG. 18 is a flow diagram showing a cleaning procedure employed in the semiconductor processing system shown above in FIG. 17, in accordance with the present invention;

FIG. 19 is a perspective view of a work area employing one or more of the semiconductor processing systems shown above in FIGS. 12 and 17; and

FIG. 20 is a block diagram showing the hierarchical control structure of system control software employed to control the semiconductor processing system, shown above in FIGS. 12 and 17, in accordance with the present invention.

### DETAILED DESCRIPTION OF THE INVENTION

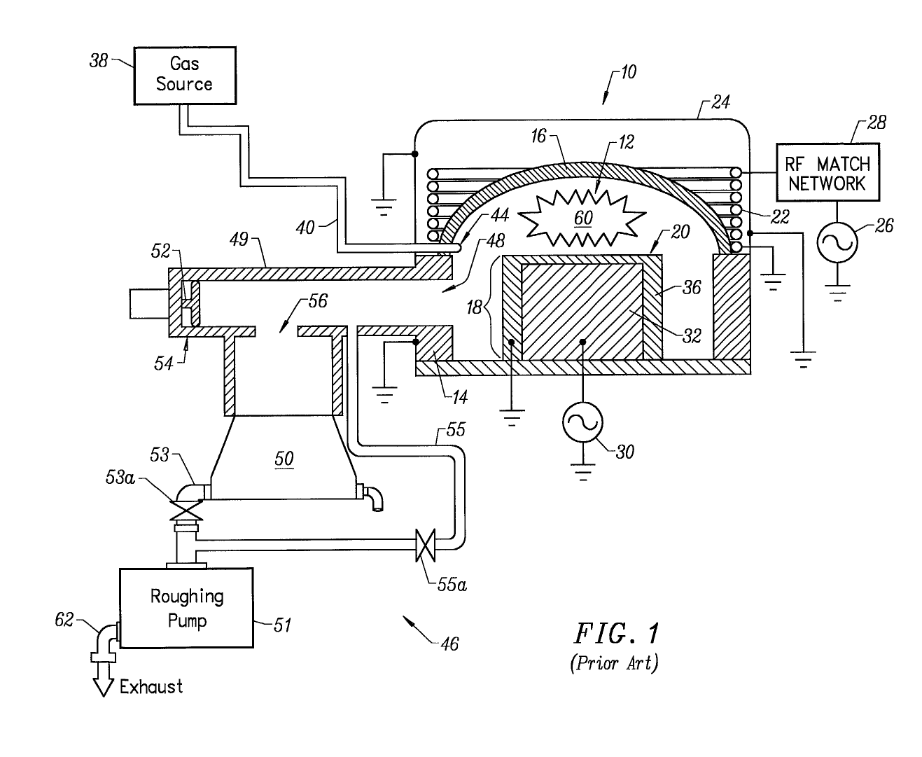

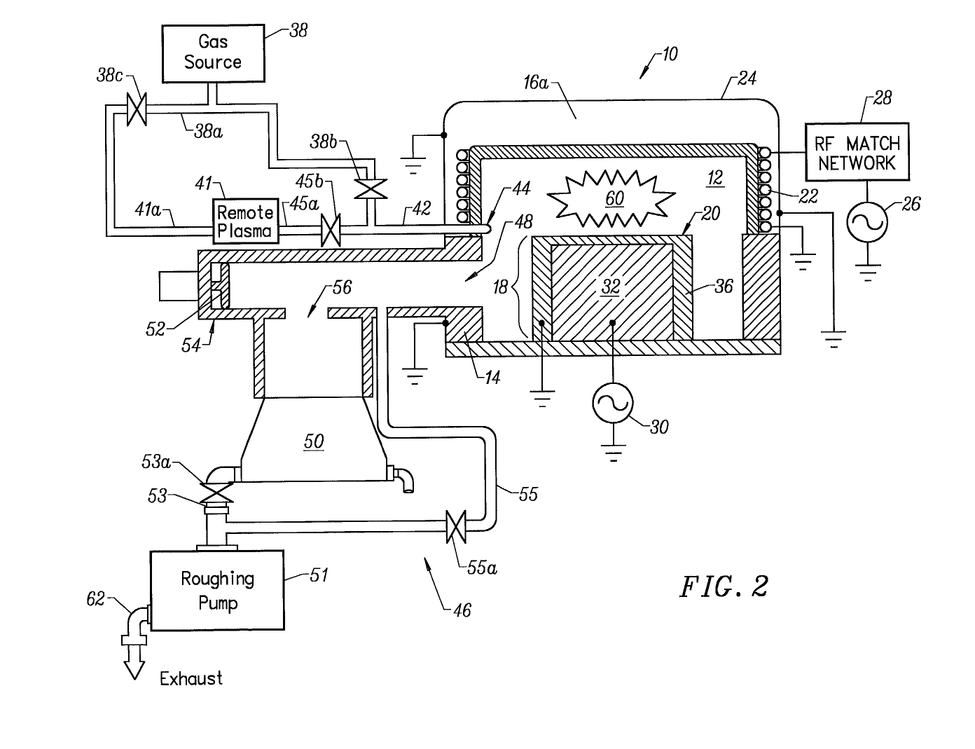

Referring to FIG. 2, a system that includes the features discussed above with respect to FIG. 1, is shown including a remote plasma system and a dielectric ceiling 16a with a rectangular shape. However, the ceiling may have any shape desired, including an arcuate shape as discussed above. The remote plasma system includes a remote plasma source 41 that may be selectively placed in fluid communication with gas source 38 via an output line 38a, a valve 38c and a feed line 41a. Activation of valve 38c places feed line 41a in fluid communication with output line 38a, thereby placing gas source 38 in fluid communication with remote plasma source 41. Processing chamber 12 is in fluid communication with remote plasma source 41 via an output line 45a. Output line 45a extends from remote plasma source terminating in a valve 45b that selectively places output line 45a in fluid communication with nozzle 44 through feed line 42. An additional valve 38b is disposed in output line 38a to selectively place output line 38a in fluid communication with feed line 42.

An exemplary semiconductor process that may be employed etches the substrate (not shown) in order to form, inter alia, trenches thereon. To that end, an etchant gas, such as NF₃, SF₆, SiF₄, Si₂F₆ and the like can be employed either alone, or in combination with, a non-fluorine containing gas such as HBr, oxygen or both. The etchant gas is passed from gas source 38 into processing chamber 12 by activation of valve 38b that places output line 38a in fluid communication with feed line 42. The process gas traverses output line 38a, feed line 42 and nozzle 44 to enter processing chamber 12. RF generators 26 and 30 are activated to create high-density plasma. To that end, in one example, RF generator 26 may provide up to about 3000 watts at 12.56 MHz. RF generator 30 may supply up to 1000 watts at a frequency in the range of 400 kHz to 13.56 MHz to the interior conductive portion 32. The chamber pressure is typically in the range of 1 to 100 milliTorr.

Referring to FIGS. 2, 3 and 4, gases exit nozzle 44 to enter processing chamber 12 at rates from about 1 sccm to 300 sccm. To ensure that surface 20, and therefore the substrate (not shown), is sufficiently exposed to the gas exiting from nozzle 44, nozzle 44 is designed to provide a divergent stream of gas that extends over surface 20. To that end, nozzle 44 has an annular aperture configuration 63, in one embodiment, which consists of an annular aperture 63a centered about a longitudinal axis 64. Aperture 63a is defined by a hollow cylindrical housing 66 and a plug 67 disposed within housing 66. Hollow cylindrical housing 66 is typically formed from ceramic and defines a chamber 66a having a diameter d₁. Plug 67 is also formed from ceramic and includes a cylindrical bulwark 67a, disposed at one end thereof, with a rod 67b extending therefrom. A diameter d₂ of bulwark 67a is coextensive with diameter d₁. A sealing member, 67c, such as an 0-ring, is disposed about bulwark 67a. Rod 67b has a diameter, d₃, having a magnitude that is less than the magnitude of diameter d₁. Plug 67 is disposed in housing 66 with sealing member 67c forming a fluid tight seal with housing 66. An annular channel (not shown) is defined between rod 67b and housing 66 and extend from bulwark 67a, terminating in aperture 63a. The width of the annular channel and, therefore, aperture 63a is defined by the difference between d₁, and d₃. Gases enter nozzle 44 through a passage 66b that extends into housing 66 in a direction transverse to longitudinal axis 64. Passage 66b is in fluid communication with the annular channel (not shown). With this configuration, nozzle 44 creates a plurality of flows of gases shown as arrows 65 that travel in various directions throughout processing chamber 12, e.g., towards ceiling 16 and surface 20 during an etch process. As a result of the etch process, residue deposits on the surfaces within processing chamber 12, including ceiling 16, and chamber sidewall 14.

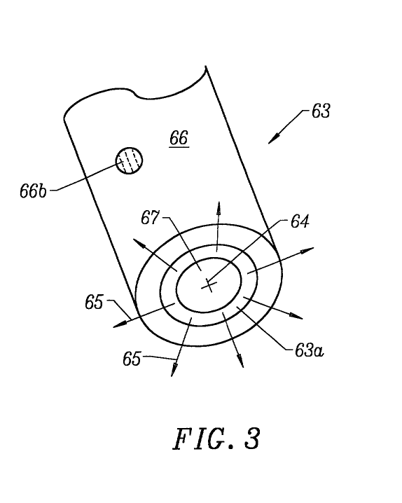

Referring again to FIG. 2, in preparation to remove the aforementioned residue, surface 20 may be exposed. To that end, the substrate (not shown) is removed from processing chamber 12. Remote plasma source 41 produces reactive radicals that include fluorine radicals, which are flowed into processing chamber 12. To that end, remote plasma source 41 is placed in fluid communication with gas source 38 by activation of valve 38c that places output line 38a in fluid communication with feed line 41a. Gases traversing feed line 41a flow into remote plasma source 41 that results in production of reactive radicals. The reactive radicals exit remote plasma source 41 and flow into processing chamber 12 by activation of valve 45b, which places output line 45a in fluid communication with feed line 42. The reactive radicals pass through feed line 42, exit nozzle 44 and enter processing chamber 12. The reactive radicals entering processing chamber 12 react with residue present to form volatile compounds in accordance with well-known processes. The annular aperture configuration 63, shown above in FIG. 3, was found to be unsuitable for cleaning processes, because a great amount of recombination of the reactive radicals occurred.

Referring to FIG. 5, 6 and 7, to improve the efficiency of nozzle 44 during both etch processes and clean process, nozzle 44 may be formed with a showerhead configuration 75. To that end, the showerhead configuration 75 includes a body 70 having interior and exterior sides 72 and 74 and an end 76. Interior side 72 defines a throughway 78 having a longitudinal axis 80. End 76 includes an opening 82 in fluid communication with throughway 78. Body 70 extends from end 76, terminating in a hemispherical region 84a. Hemispherical region 84a includes a plurality of apertures 86, each of which has a longitudinal axis 86a associated therewith that extends obliquely with respect to longitudinal axis 80.

Each of the plurality of apertures 86 have a substantially circular cross-section and are grouped in a set of three apertures 88, with one aperture of each of the sets being disposed proximate to longitudinal axis 80, another aperture of the set being disposed proximate to an interface 90 of hemispherical regions 84a and a cylindrical region 84b, with the third aperture being disposed therebetween. In this manner, each of the longitudinal axes 86a associated with apertures 86 of set 88 forms an angle with respect to longitudinal axis 80 that differs from the angle formed between the longitudinal axis 86a of the remaining apertures 86 of a set 88 and longitudinal axis 80.

With this configuration, nozzle 44 creates a plurality of flows of reactive radicals, shown generally as 44a. Flows 44a enter processing chamber 12a at various angles of trajectory θ₀, measured with respect to longitudinal axis 80 and have an initial velocity v₀ associated therewith. The velocity v₀ includes an x-component vₓ, which defines the velocity of flows 44a away from nozzle 44 along the x-axis, and a y component v_{y}, which defines the velocity of flows 44a away from nozzle 44 along the y-axis. As shown, flows 44a travel throughout processing chamber 12 and with differing degrees of turbulence, dependent upon the distance flows 44a are from nozzle 44 along the x-axis. For example, in region 57, disposed proximate to nozzle 44, flows 44a are substantially laminar and travel in a direction substantially normal to a surface of nozzle 44. In region 58, flows 44a become turbulent by virtue of the presence of a plurality of vortices, three of which are shown as 58a, 58b and 58c. Flows 44a traveling around vortices 58a, 58b and 58c collide creating substantial turbulence compared to region 57. The turbulence present in region 58 substantially reduces the velocity, vₓ, of the reactive radicals away from nozzle 44 while increasing the recombination of the same, compared to the velocity and recombination of flows 44a in region 57.

In region 59, flows 44a diffuse throughout the remaining regions of processing chamber 12a, away from nozzle 44. As a result, the velocity, vₓ, of reactive radicals associated with flows 44a in region 59 are slowest, compared to flows 44a in regions 57 and 58, resulting in the highest percentage of recombination occurring in region 59. This would result in regions within processing chamber 12a, such as region 14a and portions of ceiling 16a disposed proximate thereto, not being exposed to a sufficient flux of reactive radicals to effectively clean the same, leading to unacceptable time periods for residue removal.

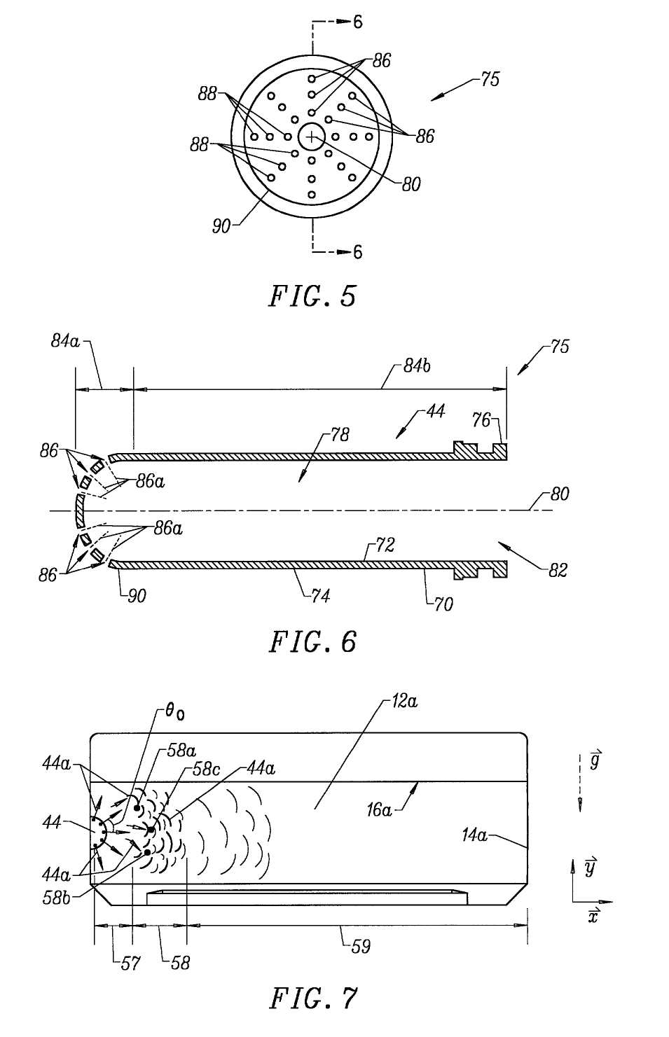

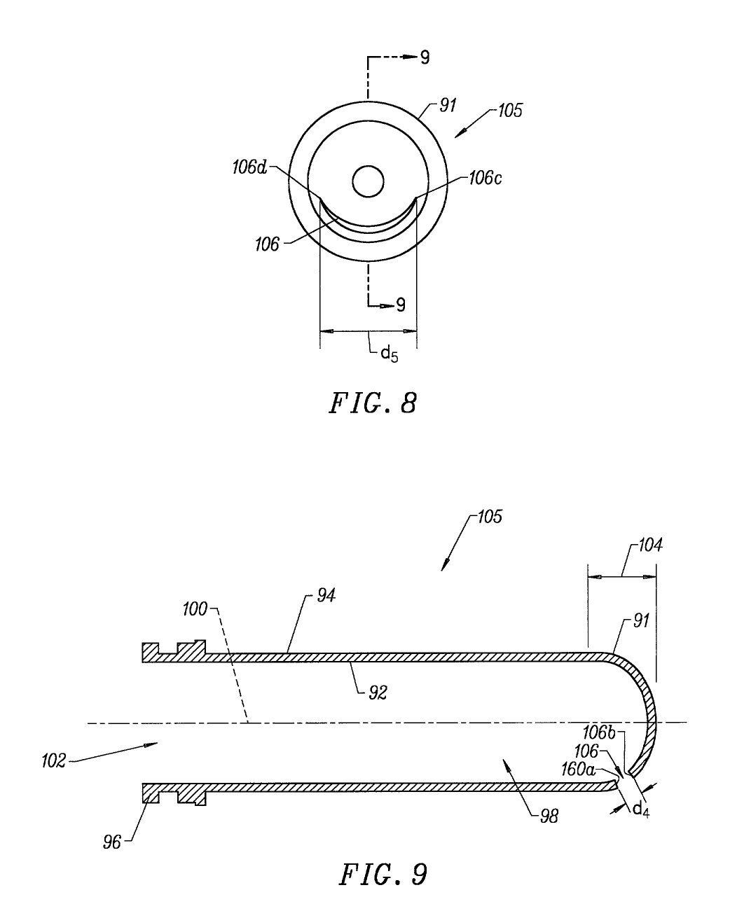

To overcome these problems presented by nozzle 44 during cleaning processes, nozzle 44, in accordance with another embodiment of the present invention, is formed with a slotted configuration 105, shown in FIGS. 8 and 9. The slotted configuration 105 replaces the plurality of apertures 86 mentioned above with respect to FIGS. 5 and 6, with a single elongated aperture 106, shown in FIG. 8.

Referring to FIGS. 8-11, in the slotted configuration 105, nozzle 44 includes a body 91 having an interior side 92 and an exterior side 94 and an end 96. Interior side 92 defines a throughway 98 having a longitudinal axis 100. End 96 includes an opening 102 in fluid communication with throughway 98. Body 91 extends from end 96, terminating in a curved hemispherical region 104, having aperture 106 formed therein. Aperture 106 defines two arcuate surfaces 106a and 106b that are spaced-apart along a first direction, a first distance, d₄. Surfaces 106a and 106b extend from a first terminus 106c along a second direction, terminating in a second terminus 106d spaced-apart from first terminus 106c, a second distance d₅. Second distance, d₅, is substantially greater than first distance d₄. Distances d₄ and d₅ are selected to provide a desired pressure differential suitable to the diameter of processing chamber 12a to ensure coverage of the same with radicals exiting nozzle 44. With aperture 106 formed in this manner, a single sheet 108 of reactive radicals is introduced into processing chamber 12a in a manner to reduce recombination of the same, discussed more fully below.

Slotted aperture configuration 105 provides superior results during cleaning processes by increasing the area of region 157 within processing chamber 12a in which a laminar flow is present. As a result a lesser percentage of recombination of reactive radicals occur in a flux of the same reaching regions of processing chamber 12a disposed remotely with respect to nozzle 44, such as region 14a. This is achieved by providing single sheet 108 of reactive radicals in which substantially all of the flows 144a of reactive radicals travel in a common direction upon exiting nozzle 44. As a result, turbulent flows of reactive radicals are avoided until reactive radicals are a greater distance, along the x-axis, from nozzle 44, compared to showerhead configuration 75, discussed above with respect to FIGS. 5-7.

Referring again to FIG. 11, sheet 108 is introduced into processing chamber 12 so that each of the plurality of flows, shown as 144a, have a common trajectory angle φ₀ that is measured with respect to an imaginary plane extending orthogonally to gravity \vec{g}. A substantial portion of flows 144a associated with sheet 108 a flow cell that is defined about a vortex 111. A sub-portion of the flows, shown as 145a, separate from sheet 108 and enter region 158. In region 158, turbulent flow results from flows 145a of reactive radicals traveling in differing directions and colliding together. The turbulence in region 158 substantially reduces the velocity vₓ of flows 145a in region 159, causing the flows 145b in region 159 to diffuse therefrom and move throughout the remaining regions of processing chamber 12a, away from nozzle 44. The turbulence in region 158 and subsequently slow velocity vₓ in region 159 results in recombination of reactive radicals associated with flows 145a and 145b. However, due to the trajectory of sheet 108 into processing chamber 12a, a greater amount of reactive radicals impinge upon surfaces therein, reducing the residue removal time to an acceptable level. Specifically, sheet 108 is introduced to impinge upon the aforementioned flow cell tangentially. This facilitates movement of reactive radicals propagating further into processing chamber 12a while avoid recombination.

Referring to both FIGS. 9 and 11, to further reduce recombination, slotted aperture configuration 105 may be fabricated from a material, such as ceramic, that provides low radical recombination rates. As a result of reduced recombination, nozzle 147 and the flow pattern shown in FIG. 11, allows a greater flux of reactive radicals to reach ceiling 16a and to be transferred elsewhere in processing chamber 12a with a greater velocity, vₓ. Thus, cleaning of the ceiling 16a and other surfaces within processing chamber 12a is greatly enhanced by increasing the quantity of residue removed per unit time.

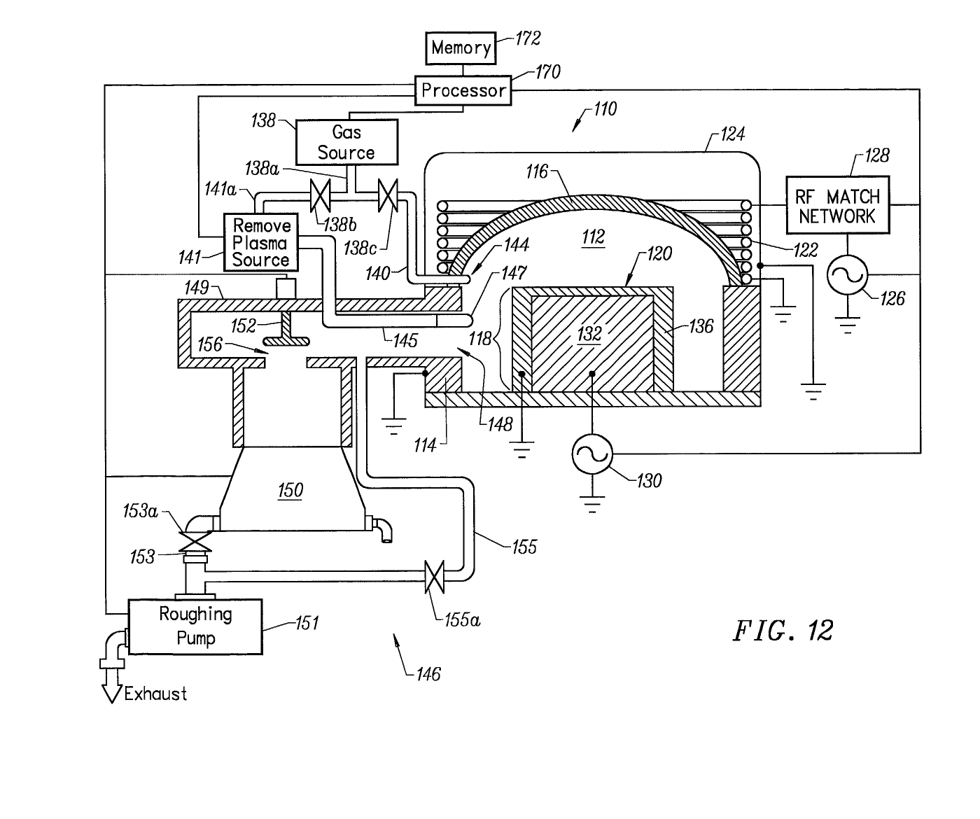

Referring to FIG. 12, another configuration of a plasma reactor 110, includes a body that defines a processing chamber 112 having a grounded, conductive, cylindrical sidewall 114 and an arcuate shaped dielectric ceiling 116, e.g., dome-like. As discussed above, however, ceiling 116 may be of any shape desired, such as a rectangular shape. Reactor 110 includes a wafer pedestal 118 disposed within processing chamber 112 and includes a surface 120 to support a semiconductor substrate (not shown). A cylindrical inductor coil 122 surrounds dielectric ceiling 116 and, therefore, an upper portion of processing chamber 112. A grounded body 124 shields inductor coil 122. An RF generator 126 is in electrical communication with inductor coil 122 through a conventional active RF match network 128. The winding of inductor coil 122 furthest away from pedestal 118 is connected to the “hot” lead of RF generator 126, and the winding closest to pedestal 118 is connected to ground. An additional RF power supply or generator 130 is in electrical communication with an interior conductive portion 132 of pedestal 118. An exterior portion 136 of pedestal 118 forms a grounded conductor that is electrically insulated from the interior conductive portion 132.

One or more gas sources, shown as 138, may be selectively placed in fluid communication with processing chamber 112 through an output line 138a, valve 138c and feed line 140. Specifically, feed line 140 extends from valve 138c and terminates in a nozzle 144 disposed in processing chamber 112. Nozzle 144 may be one of a plurality of nozzles spaced about processing chamber 112. Activation of valve 138c places feed line 140 in fluid communication with output line 138a, thereby placing gas source 138 in fluid communication with processing chamber 112.

A pump system 146 controls the chamber pressure. To that end, sidewall 114 includes an exhaust port 148 that places pump system 146 in fluid communication with processing chamber 112. Pump system 146 includes a turbo-molecular pump 150, a roughing pump 151, connected to exhaust line 153 of turbo-molecular pump 150, and a valve 152, such as a throttle gate valve or any other valve known in the art. Specifically, turbo-molecular pump 150 is selectively placed in fluid communication with roughing pump 151 through an exhaust line 153 having a foreline valve 153a disposed therein. Roughing pump 151 is also selectively placed in fluid communication with exhaust conduit 149 via pump-out line 155 having a rough pump-out valve 155a disposed therein. Valve 152 is connected between turbo-molecular pump 150 and exhaust port 148. Throttle gate valve 152 varies the area of a flow path 156 into turbo-molecular pump 150. In this manner, valve 152 typically regulates the chamber pressure in cooperation with pump 150. Pump 150 maintains a constant vacuum and throttle gate valve 152 is adjusted to provide flow path 156 with a cross-sectional area to achieve a desired chamber pressure.

A processor 170 controls the operations of reactor 110. Processor 170 is in data communication with a memory 172, as well as the various subsystems of reactor 110, including a remote plasma source 141, pump system 146, valve 152, and RF generators 126 and 130. Memory 172 may include either volatile or non-volatile memory storage devices. Examples of non-volatile memory devices include a floppy disk drive having a floppy disk, a hard disk drive, an array of hard disk drives and the like. An example of a volatile memory device includes a random access memory. Memory 172 stores a computer program that includes sets of instructions that dictate various process parameters, including the chamber pressure, RF power levels, generation of a plasma by a remote plasma source 141 and the like.

Remote plasma source 141 may be selectively placed in fluid communication with gas source 138 via output line 138a, a valve 138b and a feed line 141a. Activation of valve 138b places feed line 141a in fluid communication with output line 138a, thereby placing gas source 138 in fluid communication with remote plasma source 141. Processing chamber 112 is in fluid communication with remote plasma source 141 via a feed line 145. Feed line 145 extends from remote plasma source 141 into exhaust conduit 149, terminating in a nozzle 147 disposed in processing chamber 112.

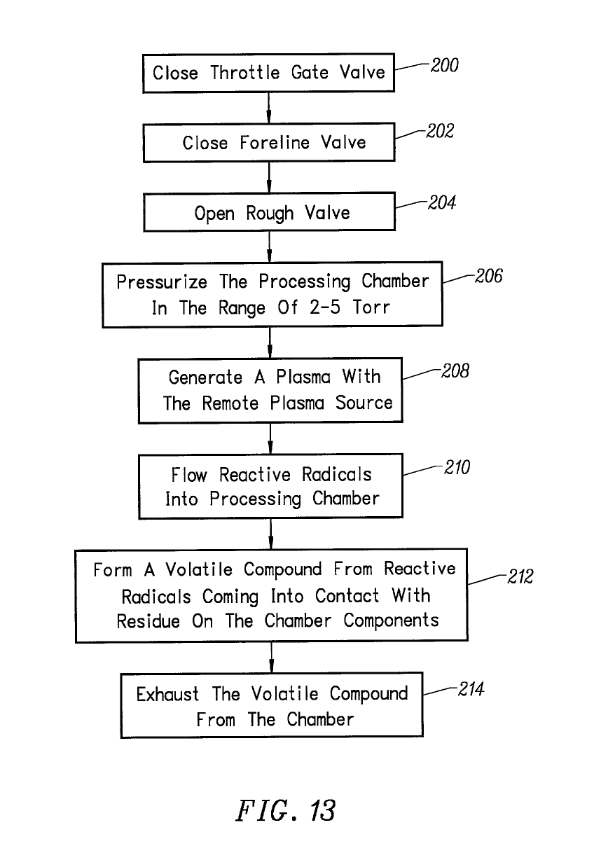

Referring to FIGS. 12 and 13, preparation for the cleaning process places valve 152 in a closed position at step 200. In this position, the valve 152 extends in to the flow path 156. This ensures that reactive radicals come in contact with the residue on valve 152. At step 202, the foreline valve 153a is closed. At step 204, the rough pump-out valve 155a, normally closed during processing operations, is opened. At step 206, the pressure in processing chamber 112 is established to be in the range of 2-5 Torr. Turbo-molecular pump 150, however, operates at a pressure range no greater than 200 milliTorr. Remote plasma source 141 operates at a pressure in the range of 2-5 Torr, inclusive. As a result, turbo-molecular 150 is isolated, and roughing pump-out valve 155a is opened to pressurize processing chamber 112 to an appropriate level. At step 208 remote plasma source 141 generates a plasma that produces fluorine radicals from molecules containing fluorine. A flow of fluorine radicals moves from remote plasma source 141 through feed line 145. After entering the portion of feed line 145 disposed in exhaust conduit 149, reactive radicals enter into processing chamber 112 through nozzle 147 at step 210. As discussed above, the fluorine radicals in the tributaries react with the residue on the components of reactor 110 form volatile compounds at step 212. The volatile compounds are exhausted from reactor 110 through the exhaust in roughing pump 151, at step 214.

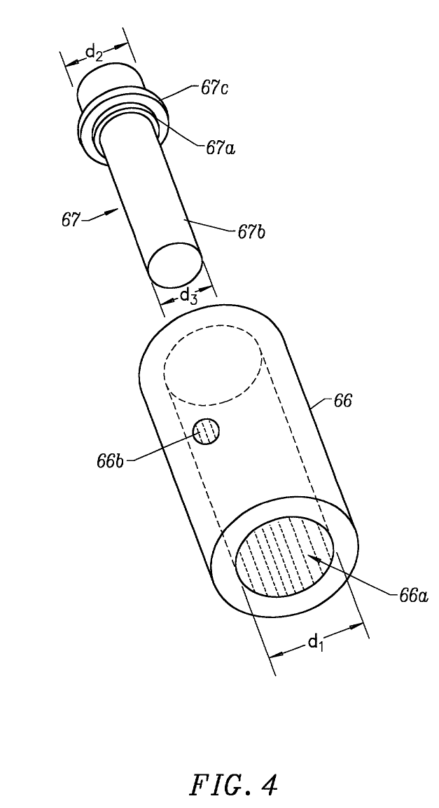

Referring to FIG. 12, selecting an appropriate design for one or more of nozzles 144 and 147 enhances the operation of plasma reactor 110. For example, nozzle 144 may be any nozzle design, including those discussed above with respect of FIGS. 3-11, and nozzle 147 may be any nozzle design including those discussed above with respect to FIGS. 5-11. However, superior results were demonstrated during etch processes by providing nozzle 144 with annular aperture configuration 63, discussed above with respect to FIGS. 3 and 4. Specifically, annular aperture configuration 63 provides better coverage of the substrate (not shown) undergoing an etch operation is achieved.

Referring to FIGS. 8, 9 and 12, it was found that providing nozzle 147 with slotted aperture configuration 105 provides superior results during cleaning processes. This is due to the enhanced cleaning of the ceiling and other surfaces within processing chamber 112 that are remotely disposed from nozzle 147, for the reasons discussed above.

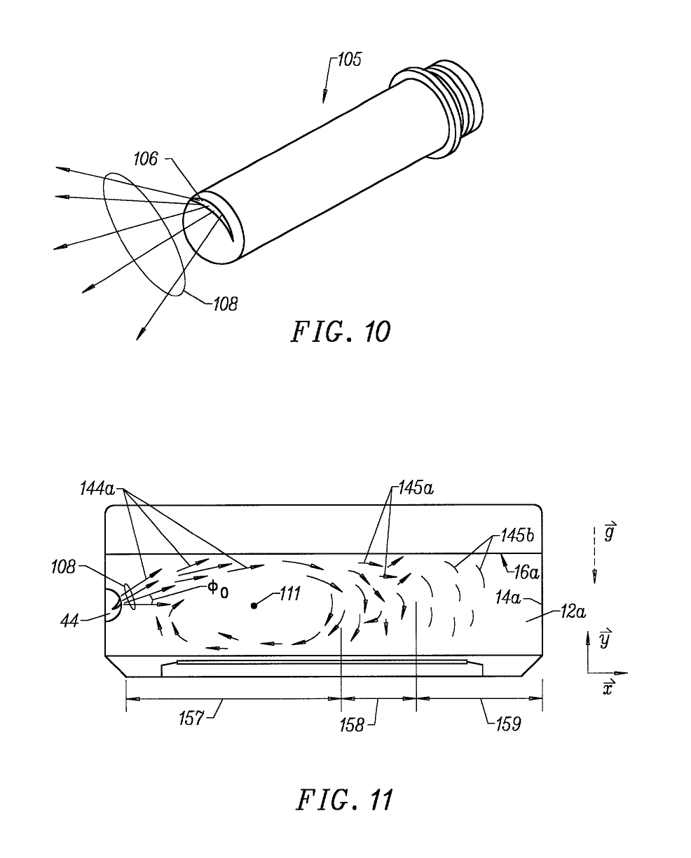

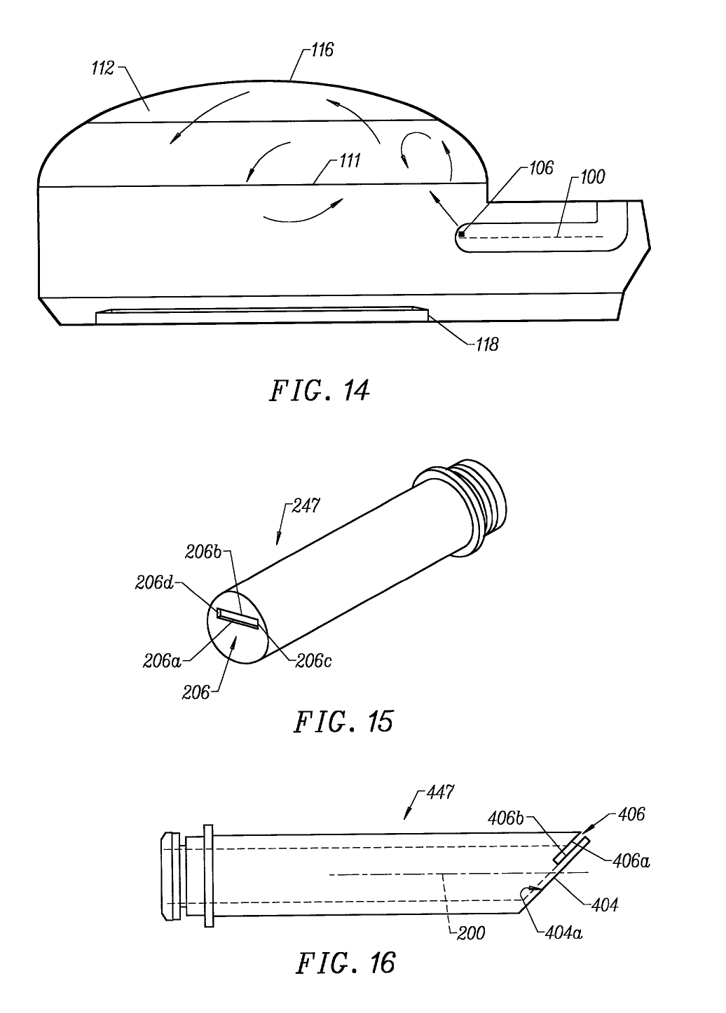

Referring again to FIGS. 10, 12 and 14, another benefit provided by nozzle 147 concerns control of direction and turbulence of the flow within processing chamber 112. For example, the direction of sheet 108 within processing chamber 112 becomes a function of the rotation of nozzle 147 about longitudinal axis 100. As shown, sheet 108 exiting aperture 106 is directed toward ceiling 116. Were nozzle 147 rotated, sheet 108 may be directed toward pedestal 18, or other regions of processing chamber 112, as desired. Thus, nozzle 147 facilitates efficiently forming and directing sheet 108 of reactive radicals to efficiently convey of reactive radicals to locations within chamber 112.

Another embodiment of nozzle 147, shown in FIG. 15 as slotted configuration 247, includes two spaced-apart surfaces 216a and 216b that extend between first and second termini 216c and 216d so as to be parallel to one another. In the simplest configuration, aperture 216 defines trapezoid, but may be rectangular in shape, as well.

Referring to both FIGS. 9 and 16, another embodiment of nozzle 147, shown in FIG. 16 as slotted configuration 447, replaces hemispherical region 104 with a planar end 404. Planar end defines a planar surface 404a that extends obliquely with respect to longitudinal axis 400. Aperture 406 is formed into body 491, proximate to planar end 404 and includes surfaces 406a and 406b. Surfaces 406a and 406b extend parallel to end 404. Surfaces 406a and 406b have the same geometric properties as discussed above with respect to surfaces 106a and 106b. In this manner, slotted configuration 447 creates a flow similar to sheet 108 that is created by slotted configuration 105, shown above in FIG. 10.

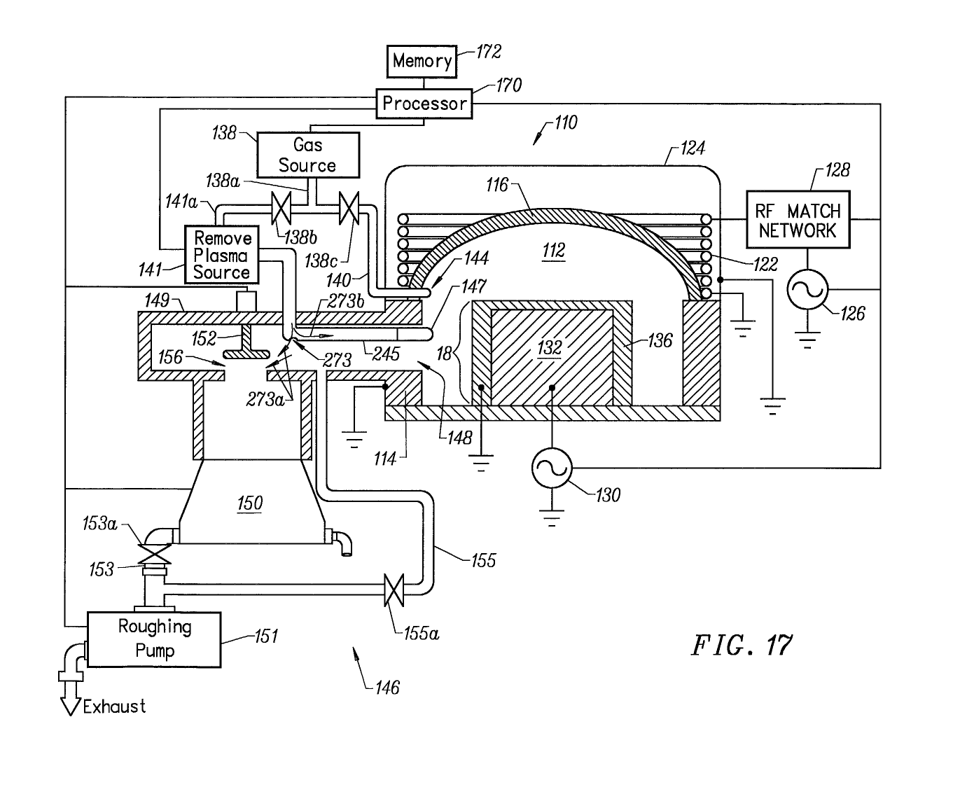

Referring to FIG. 17, another embodiment of reactor 110, in accordance with the present invention, includes all of the features discussed above with respect to FIG. 12, and also includes a feed line 245 that bifurcates the flow of reactive radicals entering exhaust conduit 149. To that end, feed line 245 includes an orifice 273 that is spaced-apart from nozzle 147 and opens into exhaust conduit 149. In this manner, a flow of fluid traversing feed line 245 is bifurcated, with a sub-portion of the fluid, shown as arrows 273a egressing from orifice 273 toward pump system 146. The remaining portion of the flow, shown as arrows 273b enters processing chamber 112 through nozzle 147.

Inclusion of orifice 273 facilitates cleaning of pump system 146 employing remote plasma source 141. Firstly, it is believed that activation of turbo-molecular pump 150 results in recombination of reactive radicals traveling through pump system 146 into less reactive molecules. This is caused by compression of reactive radicals within the pump between flow path 156 and exhaust 153. Deactivation of turbo-molecular pump 150 reduces, if not eliminates, the pressure differential and, therefore, minimizes recombination of the reactive radicals. Secondly, having orifice 273 disposed proximate to pump system 146 reduces the distance traveled by reactive radicals before reaching the same. This is believed to further reduce recombination of the reactive radicals before reaching pump system 146, thereby increasing the cleaning efficiency of the same.

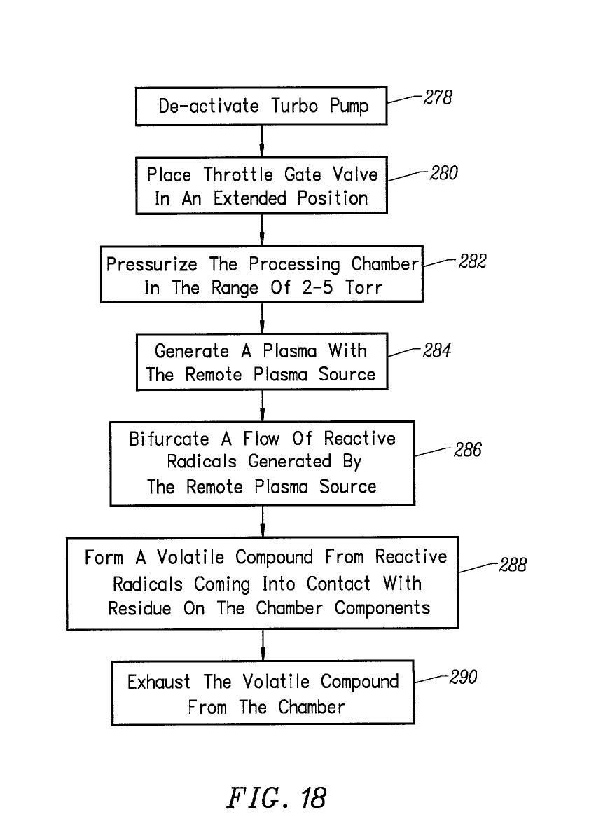

Referring to FIGS. 17 and 18, preparation for the cleaning process, in accordance with the present invention, deactivates turbo-molecular pump 150 at step 278 and places valve 152 in the extended position at step 280. This ensures that reactive radicals come in contact with the residue on valve 152. At step 282, the pressure in processing chamber 112 is established to be in the range of 2-5 Torr. Turbo-molecular pump 150, however, operates at a pressure range no greater than 200 milliTorr. Remote plasma source 141 operates at a pressure in the range of 2-5 Torr, inclusive. As a result, turbo-molecular pump 150 is deactivated and roughing pump 151 is activated to pressurize reactor 110 to the appropriate level. At step 284 remote plasma source 141 generates a plasma that produces fluorine radicals from molecules containing fluorine. A flow of fluorine radicals moves from remote plasma source 141 through feed line 245. After entering the portion of feed line 245 disposed in exhaust conduit 149, the flow of reactive radicals bifurcates, thereby creating two tributaries of radicals, shown as arrows 273a and 273b, at step 286. One of the two tributaries of reactive radicals 273b traverses nozzle 147 exiting therefrom and entering processing chamber 112. The remaining tributary of reactive radicals 273a exits feed line 245 through orifice 173 and is directed into turbo-molecular pump 150. The fluorine radicals in the tributaries react with the residue on the reactor components to form volatile compounds, at step 288. The volatile compounds are exhausted from reactor 110 through the exhaust in roughing pump 151, at step 290.

Referring to FIGS. 12, 17, and 19, the interface between a user and processor 170 may be via a visual display. To that end, one or more monitors 339a and 339b may be employed. One monitor 339a may be mounted in a clean room wall 340 having one or more reactors 310 and 311. The remaining monitor 339b may be mounted behind wall 340 for service personnel. Monitors 339a and 339b may simultaneously display the same information. Communication with processor 170 may be achieved with a light pen associated with each of monitors 339a and 139b. For example, a light pen 341a facilitates communication with processor 170 through monitor 339a, and a light pen 341b facilitates communication with processor 170 through monitor 339b. A light sensor in the tip of light pens 341a and 341b detects light emitted by CRT display in response to a user pointing the same to an area of the display screen. The touched area changes color, or a new menu or screen is displayed, confirming communication between the light pen and the display screen. Other devices, such as a keyboard, mouse, or other pointing or communication device, may be used instead of or in addition to light pens 341a and 341b to allow the user to communicate with processor 170.

As discussed above, with respect to FIGS. 12 and 17, a computer program having sets of instructions controls the various subsystems of plasma reactor 110. The computer program code may be written in any conventional computer readable programming language: for example, 68000 assembly language, C, C++, Pascal, Fortran and the like. Suitable program code is entered into a single file or multiple files using a conventional text editor and stored or embodied in a computer-readable medium, such as a memory system of the computer. If the entered code text is a high level language, the code is compiled. The resultant compiler code is then linked with an object code of precompiled Windows® library routines. To execute the linked and compiled object code the system user invokes the object code, causing the computer system to load the code in memory. Processor 170 then reads and executes the code to perform the tasks identified in the program.

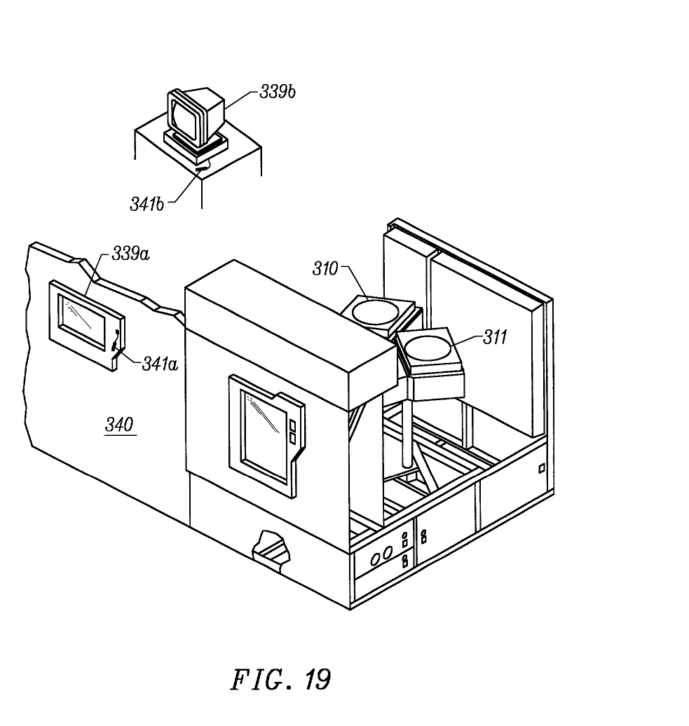

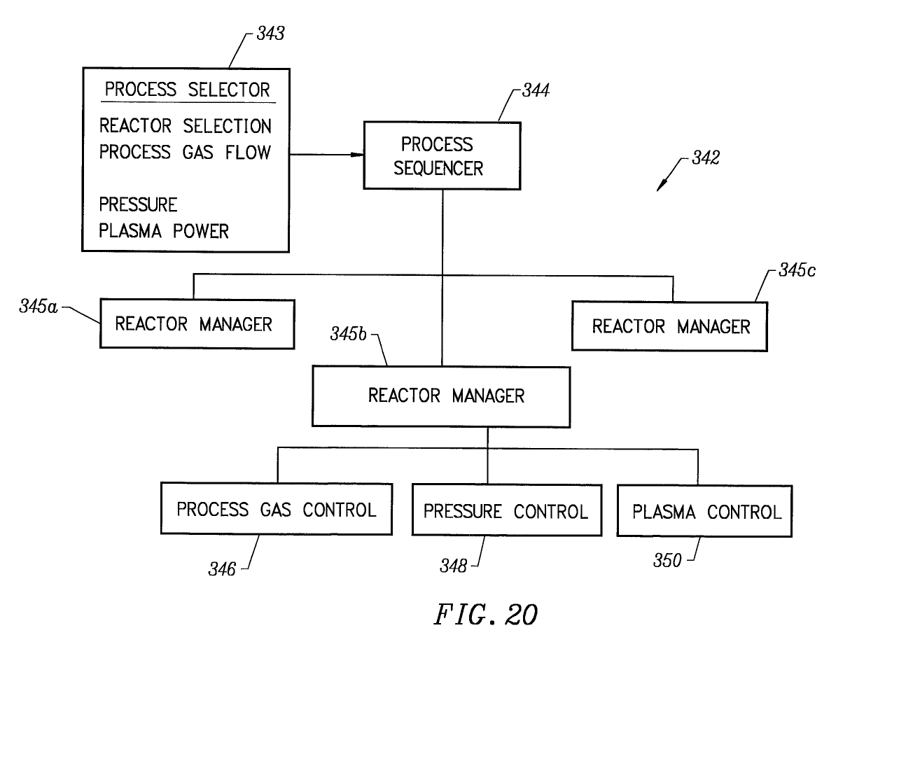

Referring to both FIGS. 19 and 20 an illustrative block diagram of the hierarchical control structure of the system control software, includes computer program 342 that a user may access using a light pen interface. For example, user may enter a process set number and reactor number into a process selector subroutine 343 in response to menus or screens displayed on the CRT monitor. Predefined set numbers identifies the process sets, which are predetermined sets of process parameters necessary to carry out specified processes. Process selector subroutine 343 identifies (i) the desired reactor 310 and 311, and (ii) the desired set of process parameters needed to operate reactor 310 and 311 for performing the desired process. The process parameters for performing a specific process relate to process conditions such as, for example, process gas composition and flow rates, pressure, plasma conditions such as high- and low-frequency RF power levels and the high- and low-frequency RF frequencies (and in addition, microwave generator power levels for embodiments equipped with remote microwave plasma systems), and cooling gas pressure. Process selector subroutine 343 controls what type of process (deposition, substrate cleaning, chamber cleaning, chamber gettering, reflowing) is performed at an appropriate time. In some embodiments, there may be more than one process selector subroutine.

A process sequencer subroutine 344 comprises program code for accepting the identified reactor 310 and 311, which may be any of the rectors discussed above with respect to FIGS. 2, 12 and 17. Referring to both FIGS. 19 and 20, process sequencer subroutine 344 also comprises program code to accept sets of process parameters from process selector subroutine 343, and to control operation of reactors 310 and 311. Multiple users can enter process set numbers and reactor numbers, or a single user can enter multiple process set numbers and reactor numbers, so sequencer subroutine 344 operates to schedule the selected processes in the desired sequence. Preferably, sequencer subroutine 344 includes program code to perform the steps of (i) monitoring the operation of reactors 310 and 311 to determine whether reactors 310 and 311 are being used, (ii) determining what processes are being carried out in reactors 310 and 311, and (iii) executing the desired process based on availability of a reactor and the type of process to be carried out. Conventional methods of monitoring reactors 310 and 311 can be used, such as polling. When scheduling the process to be executed, sequencer subroutine 344 may be designed to take into consideration the present condition of the reactor being used in comparison with the desired process conditions for a selected process, or the “age” of each particular user-entered request, or any other relevant factor a system programmer desires to include for determining scheduling priorities.

Once sequencer subroutine 344 determines which reactor and process set combination will be executed next, sequencer subroutine 344 initiates execution of the process set by passing the particular process set parameters to a reactor manager subroutine 345a-c that controls multiple processing tasks according to the process set determined by sequencer subroutine 344. For example, reactor manager subroutine 345b comprises program code for controlling operations in reactors 310 and 311. Reactor manager subroutine 345b also controls execution of various reactor component subroutines that controls operation of the reactor components necessary to carry out the selected process set. Examples of reactor component subroutines include process gas control subroutine 346, a pressure control subroutine 348, and a plasma control subroutine 350. Depending on the specific configuration of the reactor, some embodiments include all of the above subroutines, while other embodiments may include only some of the subroutines. Those having ordinary skill in the art would readily recognize that other reactor control subroutines can be included depending on what processes are to be performed in plasma reactors 310 and 311.

In operation, reactor manager subroutine 345b selectively schedules or calls the reactor component subroutines in accordance with the particular process set being executed. Reactor manager subroutine 345b schedules the reactor component subroutines much like sequencer subroutine 344 schedules which of reactors 310 and 311 and process set is to be executed next. Typically, reactor manager subroutine 345b includes steps of monitoring the various reactor components, determining which components need to be operated based on the process parameters for the process set to be executed, and initiating execution of a reactor component subroutine responsive to the monitoring and determining steps.

Process gas control subroutine 346 has program code for controlling process gas composition and flow rates. Process gas control subroutine 346 controls the open/close position of the safety shut-off valves (not shown), and also ramps up/down the mass flow controllers (not shown) to obtain the desired gas flow rate. Process gas control subroutine 346 is invoked by reactor manager subroutine 345b, as are all reactor component subroutines, and receives subroutine process parameters related to the desired gas flow rates from the reactor manager. Typically, process gas control subroutine 346 operates by opening the gas supply lines and repeatedly (i) reading the necessary mass flow controllers, (ii) comparing the readings to the desired flow rates received from reactor manager subroutine 345b, and (iii) adjusting the flow rates of the gas supply lines as necessary. Furthermore, process gas control subroutine 346 includes steps for monitoring the gas flow rates for unsafe rates, and activating the safety shut-off valves (not shown) when an unsafe condition is detected. Process gas control subroutine 346 also controls the gas composition and flow rates for clean gases as well as for deposition gases, depending on the desired process (clean or deposition or other) that is selected. Alternative embodiments could have more than one process gas control subroutine, each subroutine controlling a specific type of process or specific sets of gas lines.

Referring to FIGS. 12, 17, and 20, in some processes, an inert gas such as nitrogen, N₂, or argon, Ar, is flowed into processing chamber 112 to stabilize the pressure in the chamber before reactive process gases are introduced. For these processes, process gas control subroutine 346 is programmed to include steps for flowing the inert gas into processing chamber 112 for an amount of time necessary to stabilize the pressure in processing chamber 112, and then the steps described above would be carried out.

Additionally, when a process gas is to be vaporized from a liquid precursor, process gas control subroutine 346 would be written to include steps for bubbling a delivery gas, such as helium, through the liquid precursor in a bubbler assembly (not shown), or for introducing a carrier gas, such as helium, to a liquid injection system. When a bubbler is used for this type of process, process gas control subroutine 346 regulates the flow of the delivery gas, the pressure in the bubbler (not shown), and the bubbler temperature in order to obtain the desired process gas flow rates. To that end, process gas control subroutine 346 includes steps for obtaining the necessary delivery gas flow rate, bubbler pressure, and bubbler temperature for the desired process gas flow rate by accessing a stored table containing the necessary values for a given process gas flow rate. Once the necessary values are obtained, the delivery gas flow rate, bubbler pressure and bubbler temperature are monitored, compared to the necessary values and adjusted accordingly.

Pressure control subroutine 348 comprises program code for controlling the pressure in processing chamber 112 by regulating the size of flow path 156 provided by valve 152. The size of flow path 156 provided by valve 152 is set to control the chamber pressure at a desired level in relation to the total process gas flow, the size of processing chamber 112, and the pumping set-point pressure for pump system 146. When pressure control subroutine 348 is invoked, the desired or target pressure level is received as a parameter from reactor manager subroutine 345b. The pressure control subroutine 348 measures the pressure in processing chamber 112 by reading one or more conventional pressure manometers connected to processing chamber 112, comparing the measure value(s) to the target pressure, obtaining PID (proportional, integral, and differential) values corresponding to the target pressure from a stored pressure table, and adjusting the throttle valve according to the PID values obtained from the pressure table. Alternatively, pressure control subroutine 348 can be written to open or close valve 152 to a particular aperture size to regulate the pumping capacity in processing chamber 112 to the desired level.

A plasma control subroutine 350 comprises program code for setting low- and high-frequency RF power levels applied to the process electrodes in processing chamber 112 and pedestal 118, and for setting the low- and high-RF frequency employed. Like the previously described reactor component subroutines, plasma control subroutine 350 is invoked by reactor manager subroutine 345b. For processes employing remote plasma source 141, plasma control subroutine 350 would also include program code for controlling remote plasma source 141.

Although the foregoing has been described with respect to cleaning a reactor with a remote plasma source, it should be understood that the present invention may be employed in virtually any semiconductor processing system, such as a deposition system. Thus the embodiments that comprise the present invention should not be construed based solely upon the description recited above. Rather, the embodiments that comprise the present invention should be construed in view of the following claims, including the full scope of equivalents thereof.

What is claimed is:

1. A nozzle for a plasma reactor of a type having a processing chamber, said nozzle comprising:
a body having interior and exterior sides and a first end, with said interior side defining a throughway having a longitudinal axis, and said first end including an opening in fluid communication with said throughway, said body extending from said first end, terminating in a second end and having an aperture formed proximate to said second end, with said aperture configured to create, from a flow of fluid propagating along said throughway and exiting said aperture, a sheet of said fluid moving tangentially to a flow cell established in said processing chamber.

2. The nozzle as recited in claim 1 wherein said second end forms a planar surface extending obliquely with respect to said longitudinal axis.

3. The nozzle as recited in claim 1 wherein said second end defines a curved body, with said aperture being disposed in said curved body.

4. The nozzle as recited in claim 1 wherein said aperture defines two surfaces spaced-apart along a first direction a first distance, said spaced-apart surfaces extending from a first terminus along a second direction, transverse to said first direction, and terminating in a second terminus, spaced-apart from said first terminus a second distance, with said second distance being substantially greater than said first distance and said two spaced-apart surfaces extending between said interior and exterior sides.

5. The nozzle as recited in claim 4 wherein said two spaced-apart surfaces form an oblique angle with respect to said longitudinal axis.

6. The nozzle as recited in claim 4 wherein said two spaced-apart surfaces extend parallel to said longitudinal axis.

7. The nozzle as recited in claim 1 wherein said second end has a first axis of symmetry and a second axis of symmetry, extending transversely to said first axis of symmetry, with said aperture lying in said first axis of symmetry and being spaced-apart from said second axis of symmetry.

8. The nozzle as recited in claim 1 wherein said second end is radially symmetrically disposed about said longitudinal axis, with said aperture being spaced-apart from said longitudinal axis.

9. The nozzle as recited in claim 1 wherein said semiconductor processing chamber further includes a remote plasma source, to produce reactive radicals, in fluid communication therewith, with said nozzle being connected between said remote plasma source and said processing chamber with reactive radicals moving from said remote plasma source toward said processing chamber entering said opening, traversing said throughway and exiting said aperture to form said flow, with said flow forming a single vortex about which said flow cell is defined.

10. A nozzle for a plasma reactor of a type having a processing chamber, said nozzle comprising:
a body having interior and exterior sides and a first end, with said interior side defining a throughway having a longitudinal axis, and said first end including an opening in fluid communication with said throughway, said body extending from said end, terminating in a second end and having an aperture formed therein proximate to said second end, with said aperture defining two surfaces spaced-apart along a first direction a first distance, said spaced-apart surfaces extending from a first terminus along a second direction, transverse to said first direction, and terminating in a second terminus, spaced-apart from said first terminus a second distance, with said second distance being substantially greater than said first distance and said two spaced-apart surfaces extending between said interior and exterior sides forming an oblique angle with respect to said longitudinal axis.

11. The nozzle as recited in claim 10 wherein said second end has a first axis of symmetry and a second axis of symmetry, extending transversely to said first axis of symmetry, with said aperture being bifurcated by said first axis of symmetry and being spaced-apart from said second axis of symmetry.

12. The nozzle as recited in claim 11 wherein said second end is radially symmetrically disposed about said longitudinal axis, with said aperture being spaced-apart from said longitudinal axis.

13. The nozzle as recited in claim 12 wherein said portion of said body extending between said end and said second end defines a cylindrical region symmetric about said longitudinal axis, with said second end being radially and symmetrically disposed about said longitudinal axis, with said aperture being disposed between said longitudinal axis and an interface of said curved and cylindrical regions.

14. The nozzle as recited in claim 13 wherein said semiconductor processing chamber further includes a remote plasma source, to produce reactive radicals, in fluid communication therewith, with said aperture being disposed within said processing chamber and said opening coupled to said remote plasma source, with reactive radicals moving toward said processing chamber entering said opening and exiting said aperture to form a flow of reactive radicals within said processing chamber about a single vortex.

15. A nozzle for a plasma reactor of a type having a processing chamber, said nozzle comprising:
a body having interior and exterior sides and a first end, with said interior side defining a throughway having a longitudinal axis, and said first end including an opening in fluid communication with said throughway, said body extending from said first end, terminating in a second end and having an aperture formed proximate to said second end, said aperture defining two surfaces spaced-apart along a first direction a first distance, said spaced-apart surfaces extending from a first terminus along a second direction, transverse to said first direction, and terminating in a second terminus, spaced-apart from said first terminus a second distance, with said two spaced-apart surfaces extending between said interior and exterior sides and said second distance being substantially greater than said first distance to produce, from a fluid stream traversing said throughway and exiting said aperture, a flow of a substantially planar sheet of fluid.

16. The nozzle as recited in claim 15 wherein said sheet of fluid produces a flow cell within said chamber and said aperture provides said substantially planar sheet of fluid exiting therefrom with a trajectory angle, φ₀, so that said planar sheet impinges upon said flow cell, tangentially.

17. The nozzle as recited in claim 15 wherein said second end forms a planar surface extending obliquely with respect to said longitudinal axis.

18. The nozzle as recited in claim 15 wherein said second end defines a curved body, with said aperture being disposed in said curved body.

19. The nozzle as recited in claim 15 wherein said second end has a first axis of symmetry and a second axis of symmetry, extending transversely to said first axis of symmetry, with said aperture being bifurcated by said first axis of symmetry and being spaced-apart from said second axis of symmetry.

20. The nozzle as recited in claim 15 wherein said curved body is radially and symmetrically disposed about said longitudinal axis, with said aperture being spaced-apart from said longitudinal axis.
